(19) United States
(12) Patent Application Publication
(10) Pub. No.: US 2020/0404798 A1
(43) Pub. Date: Dec. 24, 2020

(54) QUICKLY DETACHABLE AND REPAIRABLE ELECTRICAL FACILITY

(71) Applicant: Oxti Corporation, Taipei (TW)

(72) Inventor: Chih Feng HO, Taipei (TW)

(21) Appl. No.: 16/449,589

(22) Filed: Jun. 24, 2019

(51) Int. Cl. H05K 5/02; H05K 5/00; H05K 5/03

(52) U.S. Cl. CPC H05K 5/0204; H05K 5/0004; H05K 5/0047; H05K 5/03; H05K 5/0247; H05K 5/0221

(57) ABSTRACT

An electrical facility for a supporting device includes a housing having two housing members each of which include a chamber, the housing members each include an opening formed in a side edge of the housing, a lock member includes one or more lock pins for engaging with the housing members and for locking the lock member to the housing members, and a cover is engaged with the lock member and the housing members. The housing members each include a lock element for engaging with the lock pin. The lock member includes a protrusion for engaging with a slot of the cover and for anchoring the cover to the lock member and the housing members.

### BACKGROUND OF THE INVENTION

### 1. Field of the Invention

The present invention relates to an electrical facility, and more particularly to an electrical facility including an improved structure or configuration for allowing the electrical facility to be easily and quickly and readily attached or mounted or secured to a clamp or support device that may be used for attaching or mounting or securing to a supporting desk or the like, and to be easily and quickly disengaged and detachable from the support device and to be easily and quickly repaired after being disengaged and detached from the support device.

### 2. Description of the Prior Art

Typical electrical facilities, such as displays, monitors, notebooks, portable or mobile phones, iPads or the like may be required to be attached or mounted or secured to a supporting desk or the like with a clamping device or supporting device which comprises a screw clamp for engaging with the supporting desk or the like and for attaching or mounting or securing the clamping or supporting device and the electrical facilities to the supporting desk or the like.

For example, U.S. Pat. No. 5,713,549 to Shieh, U.S. Pat. No. 6,769,657 B1 to Huang, and U.S. Pat. No. 7,395,995 to Chen disclose several of the typical clamping devices or supporting devices for attaching or mounting or securing the electrical facilities to the supporting desk or the like.

However, the typical clamping devices or supporting devices includes a complicated structure or configuration that may not be easily and quickly made or manufactured and that may include a large number of parts and elements for attaching or mounting or securing the electrical facilities to the clamping devices or supporting devices, and that may include a complicated making or manufacturing procedure, and that may include a greatly increased manufacturing cost.

The present invention has arisen to mitigate and/or obviate the afore-described disadvantages of the conventional electrical facilities.

### SUMMARY OF THE INVENTION

The primary objective of the present invention is to provide an electrical facility including an improved structure or configuration for allowing the electrical facility to be easily and quickly and readily attached or mounted or secured to a clamp or support device that may be used for attaching or mounting or securing to a supporting desk or the like, and to be easily and quickly disengaged and detachable from the support device and to be easily and quickly repaired after being disengaged and detached from the support device.

In accordance with one aspect of the invention, there is provided an electrical facility for a supporting device comprising a housing including two housing members, the housing members each including a chamber formed in the respective housing member, the housing members each including an opening formed in the respective housing member and defined in a side edge, a lock member including at least one lock pin extended therefrom for engaging with the housing members and for locking the lock member to the housing members, and a cover engaged with the lock member and the housing members for covering and shielding the lock member and the housing members.

The housing members each include a lock element formed in the side edge for receiving and engaging with the at least one lock pin. The cover includes a slot formed in the cover for receiving and engaging with a stud of a supporting device. The lock member includes a protrusion extended from the lock member for engaging with the slot of the cover and for anchoring the cover to the lock member.

The housing members each include a plurality of connectors provided therein. The housing includes a circuit board engaged in each of the housing members, and the connectors are provided on the circuit boards respectively. The housing includes at least one flap extended therefrom. The cover includes a notch formed in the cover for engaging with a base anchor of the supporting device or the like.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a side plan schematic view illustrating the attachment of an electrical facility in accordance with the present invention to a supporting desk or the like with a clamping device or supporting device;

FIG. 2 is a perspective view of the electrical facility and the clamping device or supporting device;

FIGS. 3, 4 are perspective views similar to FIG. 2, illustrating the operation of the electrical facility;

FIG. 5 is a partial exploded view of the electrical facility;

FIG. 6 is another partial exploded view of the electrical facility; and

FIG. 7 is a further partial exploded view of the electrical facility.

### DETAILED DESCRIPTION OF THE PREFERRED EMBODIMENT

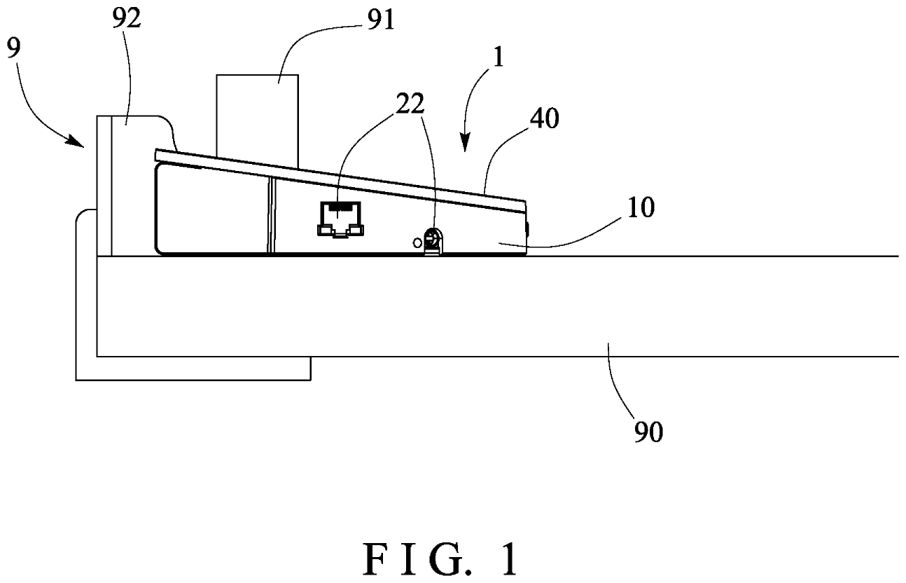

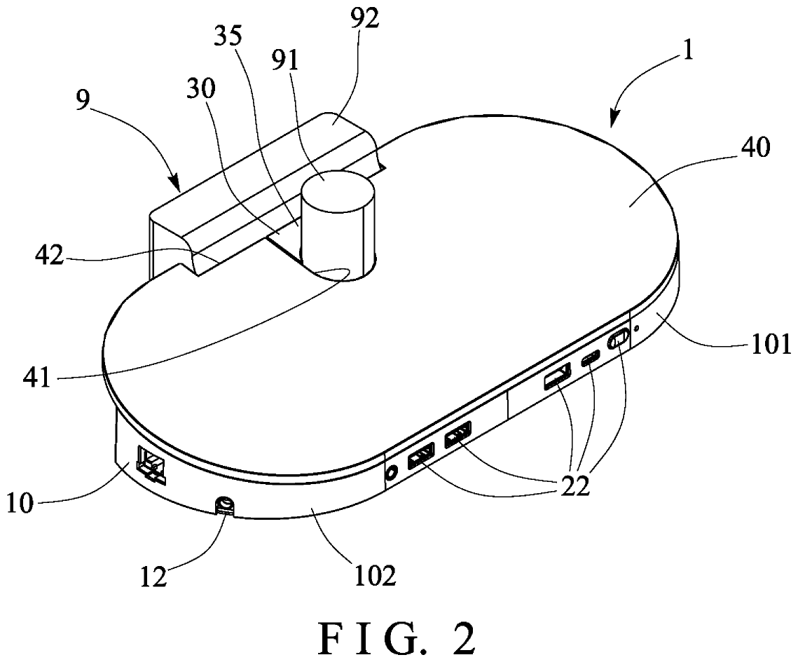

Referring to the drawings, and initially to FIGS. 1 and 2, an electrical facility in accordance with the present invention comprises an electrical facility body member or housing 10 for attaching or mounting or securing to a supporting desk 90 or object or the like with a clamping device or supporting device 9 which normally includes a pole or stud 91 formed or provided thereon or extended therefrom for engaging with and for attaching or mounting or securing the electrical facility 1 to the supporting desk 90 or object or the like. The electrical facility 1 may be selected from a display, a monitor, a notebook, a portable or mobile phone, an iPad, a calculator, a keyboard, a remote control device or the like and may be provided for attaching to the supporting desk 90 with the supporting device 9.

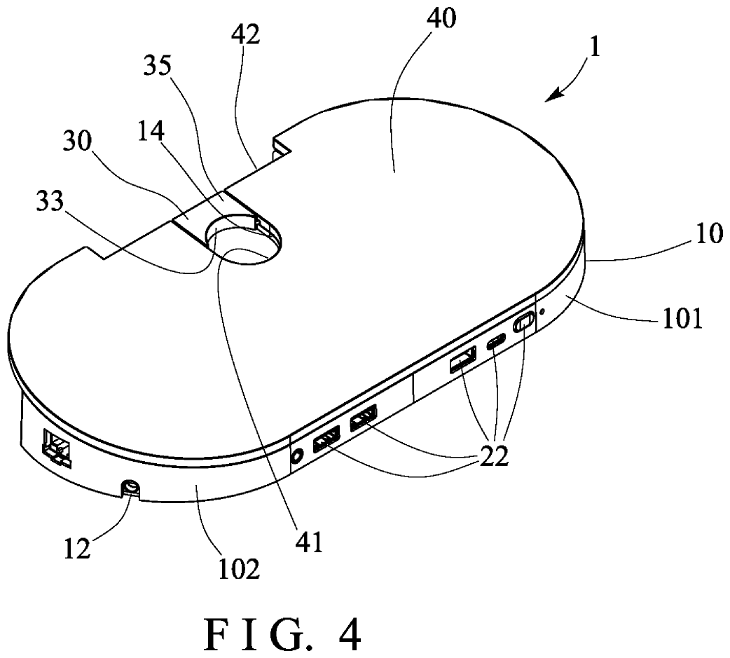

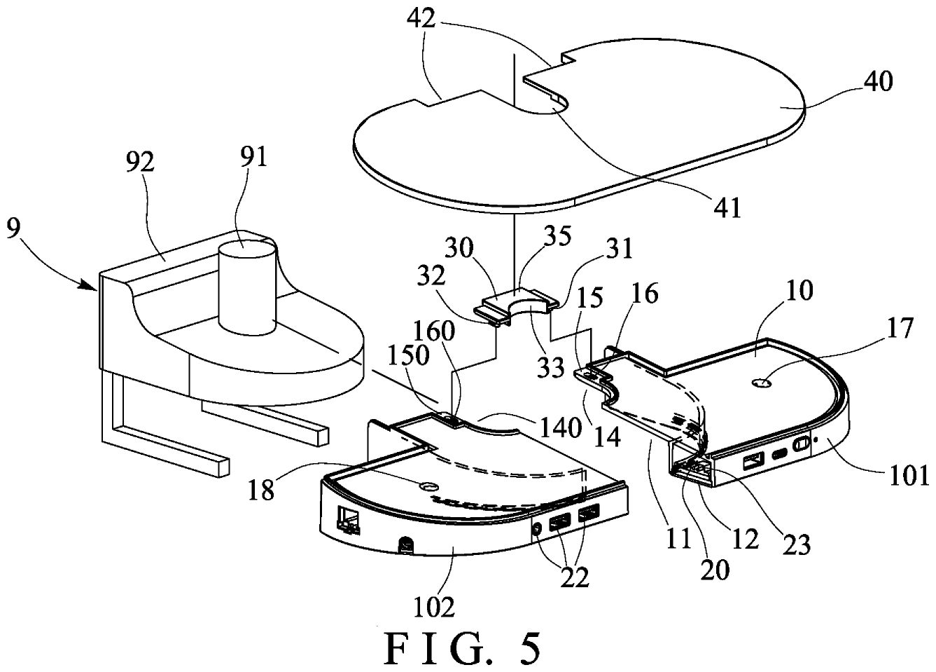

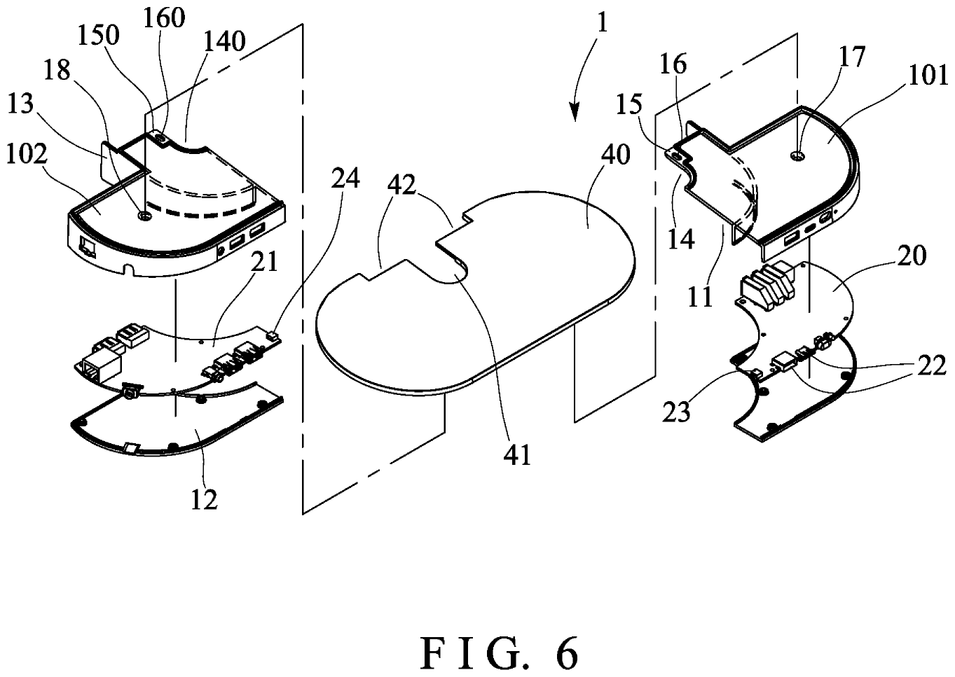

As shown in FIGS. 2-6, the housing 10 of the electrical facility 1 includes two housing members 101, 102 each having a compartment or chamber 11 formed therein (FIGS. 5, 6) for receiving or engaging with a portion, such as a base anchor 92 of the supporting device 9, and each having a bottom wall or panel 12 attached or mounted or secured to the lower or bottom portion the respective housing member 101, 102, and each having an ear or flap 13 extended therefrom for engaging with the base anchor 92 of the supporting device 9 and for solidly and stably anchoring or retaining or positioning the housing members 101, 102 of the housing 10 to the supporting device 9 and for preventing the housing members 101, 102 of the housing 10 from moving sidewise relative to the supporting device 9.

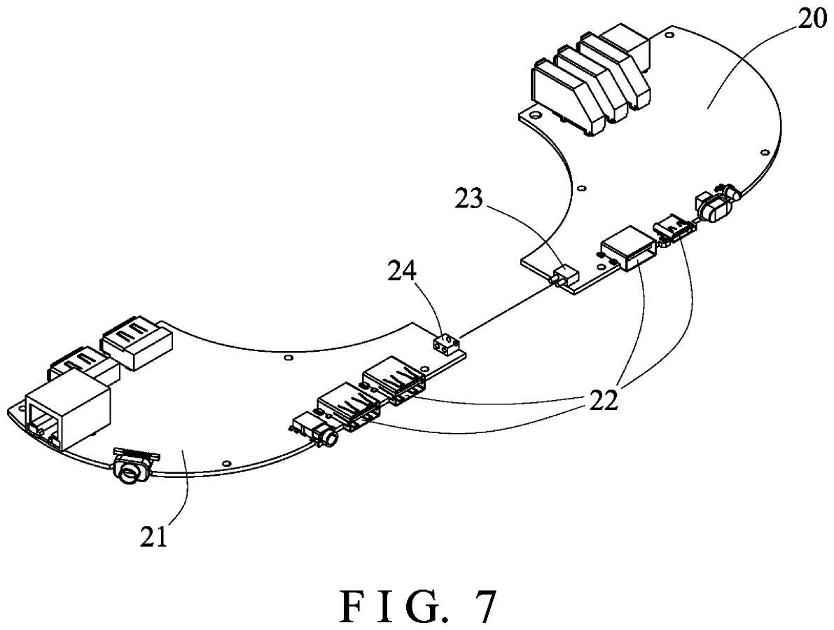

As shown in FIGS. 6 and 7, one or more (such as two) circuit boards 20, 21 are disposed or engaged onto the housing members 101, 102 of the housing 10 respectively, and each include a number of sockets or terminals or connectors 22 formed or provided thereon for electrically connecting or coupling to various electrical devices or appliances (not illustrated), and the connectors 22 are exposed or extended out of the housing members 101, 102 or reachable from outside of the housing members 101, 102 for allowing the connectors 22 to be connected or coupled to the electrical devices or appliances (not illustrated) or the like. One of the circuit boards 20 includes a male terminal or coupler 23 formed or provided thereon, and the other circuit board 21 includes a female or second terminal or connector 24 formed or provided thereon for selectively engaging with the coupler 23 of the circuit board 20 and for electrically connecting or coupling the circuit boards 20, 21 together.

The housing 10 further includes an oblong hole or opening 14, 140 formed therein (FIGS. 5, 6), such as formed in the respective housing member 101, 102 and formed in a respective side edge 15, 150, and/or communicating with the chamber 11 of the housing 10, and for receiving or engaging with the stud 91, and for further solidly and stably anchoring or retaining or positioning the housing members 101, 102 of the housing 10 to the supporting device 9. The housing members 101, 102 of the housing 10 each further includes a lock orifice or lock element 16, 160 formed therein, such as formed in the respective side edge 15, 150 thereof respectively. The housing members 101, 102 of the housing 10 each further includes one or more orifices or apertures 17, 18 formed therein for heat dissipating purposes or the like.

The electrical facility 1 further includes a fastener or lock member 30 attached or mounted or secured to the housing 10 and contacted or engaged with the stud 91 of the supporting device 9 for further solidly and stably anchoring or retaining or positioning or locking the housing 10 to the supporting device 9. The lock member 30 includes one or more (such as two) lock tongues or lock pins 31, 32 extended therefrom (FIG. 5) for engaging with the lock elements 16, 160 of the housing members 101, 102 of the housing 10 and for locking or securing the lock member 30 to the housing 10 and also for solidly and stably anchoring or retaining or positioning or locking the housing 10 to the stud 91 of the supporting device 9. It is preferable, but not necessary that the lock member 30 includes a curved recess 33 formed therein for suitably engaging with the stud 91 that includes a cylindrical shape or structure or configuration having a circular cross section. The curved recess 33 of the lock member 30 and the openings 14, 140 of the housing members 101, 102 of the housing 10 may include a circular shape or cross section for suitably receiving or engaging with the stud 91.

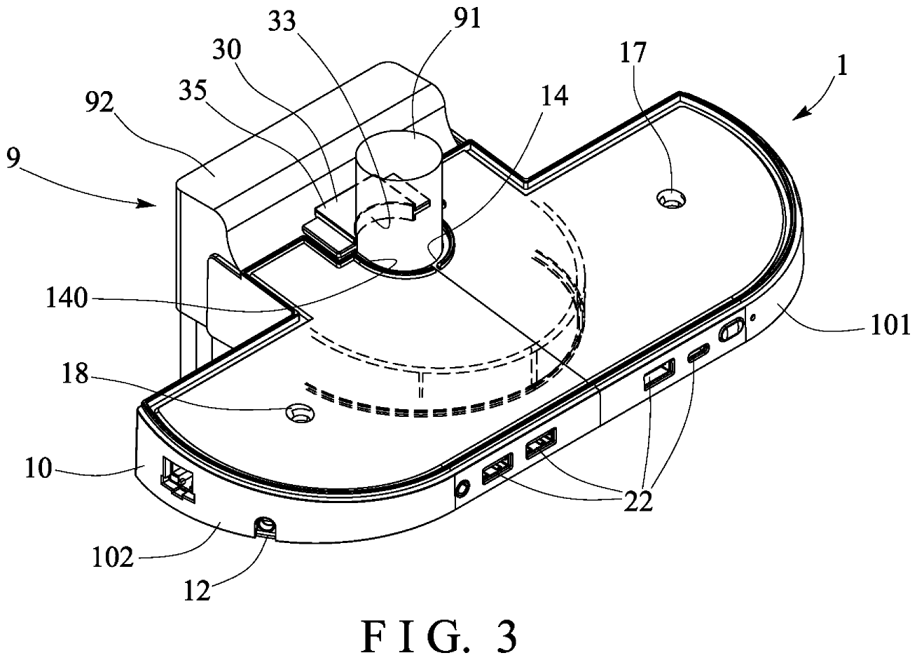

The electrical facility 1 further includes a cap or cover 40 for engaging onto the housing 10, and the cover 40 also includes an oblong hole or slot 41 formed therein for receiving or engaging with the stud 91 (FIGS. 2, 3), and a notch 42 formed therein for engaging with the base anchor 92 of the supporting device 9 and for solidly and stably anchoring or retaining or positioning the cover 40 to the housing 10 and the supporting device 9. The lock member 30 may further include a bulge or protrusion 35 (FIGS. 2-5) extended therefrom for engaging with the slot 41 of the cover 40 and for further solidly and stably anchoring or retaining or positioning the cover 40 to the lock member 30 and the housing 10. The cover 40 may be solidly and stably attached or mounted or secured to the housing 10 with screws or bolts or catches or latches or fasteners (not illustrated) or with welder or adhesive materials or the like, for partially covering the lock member 30 and for covering and shielding the housing 10.

It is to be noted that the housing members 101, 102 of the housing 10 and the circuit boards 20, 21 may be easily and quickly disengaged and detached or separated from the supporting device 9 and may be easily and quickly repaired or changed with the new ones after being disengaged and detached from the supporting device 9.

Accordingly, the electrical facility in accordance with the present invention includes an improved structure or configuration for allowing the electrical facility to be easily and quickly and readily attached or mounted or secured to a clamp or support device that may be used for attaching or mounting or securing to a supporting desk or the like, and to be easily and quickly disengaged and detachable from the support device and to be easily and quickly repaired after being disengaged and detached from the support device.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. An electrical facility for a supporting device comprising:
a housing including two housing members, said housing members each including a chamber formed in said respective housing member, said housing members each including an opening formed in said respective housing member and defined in a side edge,
a lock member including at least one lock pin extended therefrom for engaging with said housing members and for locking said lock member to said housing members, and
a cover engaged with said lock member and said housing members.

2. The electrical facility as claimed in claim 1, wherein said housing members each include a lock element formed in said side edge for receiving and engaging with said at least one lock pin.

3. The electrical facility as claimed in claim 1, wherein said cover includes a slot formed in said cover.

4. The electrical facility as claimed in claim 3, wherein said lock member includes a protrusion extended from said lock member for engaging with said slot of said cover and for anchoring said cover to said lock member.

5. The electrical facility as claimed in claim 1, wherein said housing members each include a plurality of connectors provided therein.

6. The electrical facility as claimed in claim 5, wherein said housing includes a circuit board engaged in each of said housing members, and said connectors are provided on said circuit boards respectively.

7. The electrical facility as claimed in claim 1, wherein said housing includes at least one flap extended therefrom.

8. The electrical facility as claimed in claim 1, wherein said cover includes a notch formed in said cover.
